(19) United States
(12) Patent Application Publication
(10) Pub. No.: US 2009/0272514 A1
(43) Pub. Date: Nov. 5, 2009

(54) POWER SUPPLY AND HEAT-DISSIPATING METHOD OF THE POWER SUPPLY

(75) Inventors: Jung-Fa Chen, Tamshui Chen (TW); Wen-Hsiung Chen, Tamshui Chen (TW)

Correspondence Address: PAI PATENT & TRADEMARK LAW FIRM, 1001 FOURTH AVENUE, SUITE 3200, SEATTLE, WA, 98154, US

(73) Assignee: ACBEL POLYTECH INC., Tamshui Chen (TW)

(21) Appl. No.: 12/114,733

(22) Filed: May 2, 2008

(51) Int. Cl. H02B 1/56; H05K 7/20

(52) U.S. Cl. 165/121; 361/678

(57) ABSTRACT

A power supply is mounted in a case for a computer and has a shell, a blower assembly and multiple electrical components. The shell has a rear surface, a heat sink chamber, an electrical component chamber, an air inlet and an air outlet. The chambers have front end communicating with each other. The air inlet and the air outlet are formed through the rear surface of the shell. The blower assembly is mounted in the shell and is adjacent to the rear surface of the shell. The electrical components are mounted in the electrical component chamber and generate heat when the computer operates. The heat-dissipating method of the power supply is to extract air from outside the computer case into the shell to dissipate the heat generated by the electrical components. Using air at room temperature from outside the case is much more efficient to cool down the power supply.

### BACKGROUND OF THE INVENTION

1. Field of the Invention

The invention relates to a power supply, and more particularly to a power supply having an improved heat-dissipating device to help dissipating heat generated by electrical components in the power supply.

2. Description of the Prior Arts

As computers become more and more powerful to process more information, more quickly, power supplies with higher power are needed to provide greater electric power for operating the computers. However, as the power supply provides more electric power, heat generated from the power supply increases proportionally and heat dissipation becomes a significant problem.

Computers comprise a case. The case has an inside chamber, a rear surface, a vent, computer components and a conventional power supply. The vent is formed through the rear surface. The computer components are mounted in the chamber of the computer case. The power supply is mounted in the chamber of the case and has a heat-dissipating device.

A conventional heat-dissipating device is mounted in the conventional power supply and comprises a shell and a blower.

The shell comprises electrical components and is mounted securely against the rear surface of the computer case, corresponds to the vent and has multiple side surfaces, an outlet and an inlet. The outlet is formed through one of the side surfaces and aligns with the vent of the computer case. The inlet is formed on another one of the side surfaces and communicates with the inside chamber of the case.

The blower is mounted inside the shell near the outlet and faces the outlet to pull the air from inside the case over the electrical components to absorb their heat before expelling the air through the outlet. However, when the computer is operating, air inside the computer case is heated by the computer components and this heated air cannot cool the power supply effectively.

To overcome the shortcomings, the present invention provides a power supply to mitigate or obviate the aforementioned problems.

### SUMMARY OF THE INVENTION

The primary objective of the present invention is to provide a power supply to dissipate the heat generated by electrical components in the power supply.

A power supply is mounted in a case for a computer and has a shell, a blower assembly and multiple electrical components. The shell has a rear surface, a heat sink chamber, an electrical component chamber, an air inlet and an air outlet. The chambers have front end communicating with each other. The air inlet and the air outlet are formed through the rear surface of the shell. The blower assembly is mounted in the shell and is adjacent to the rear surface of the shell. The electrical components are mounted in the electrical component chamber and generate heat when the computer operates. The heat-dissipating method of the power supply is to extract air from outside the computer case into the shell to dissipate the heat generated by the electrical components. Consequently, using the air at room temperature from outside the case is much more efficient to cool down the power supply.

Other objectives, advantages and novel features of the invention will become more apparent from the following detailed description when taken in conjunction with the accompanying drawings.

### BRIEF DESCRIPTION OF THE DRAWINGS

FIG. 1 is an operational perspective view of a first embodiment of a power supply in accordance with the present invention mounted in a computer;

FIG. 2 is a perspective view of the power supply in FIG. 1;

FIG. 3 is an operational side view in partial section of a second embodiment of the power supply in accordance with the present invention;

FIG. 4 is an operational side view in partial section of a third embodiment of the power supply in accordance with the present invention;

FIG. 5 is an operational side view in partial section of a fourth embodiment of the power supply in accordance with the present invention;

FIG. 6 is an operational side view in partial section of a fifth embodiment of the power supply in accordance with the present invention; and

FIG. 7 is an operational side view in partial section of a sixth embodiment of the power supply in accordance with the present invention.

### DETAILED DESCRIPTION OF THE PREFERRED EMBODIMENTS

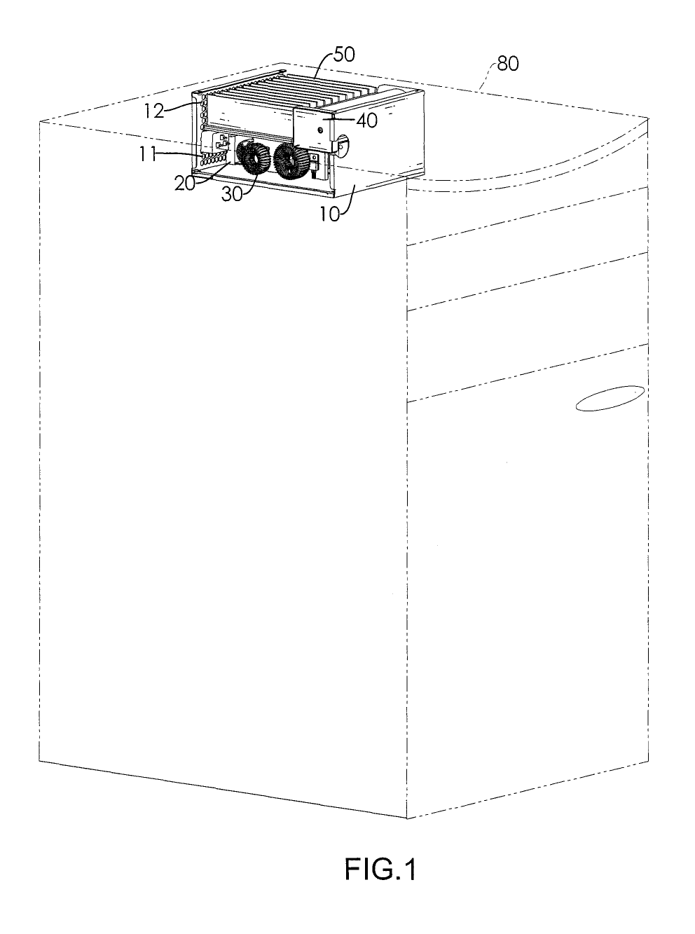

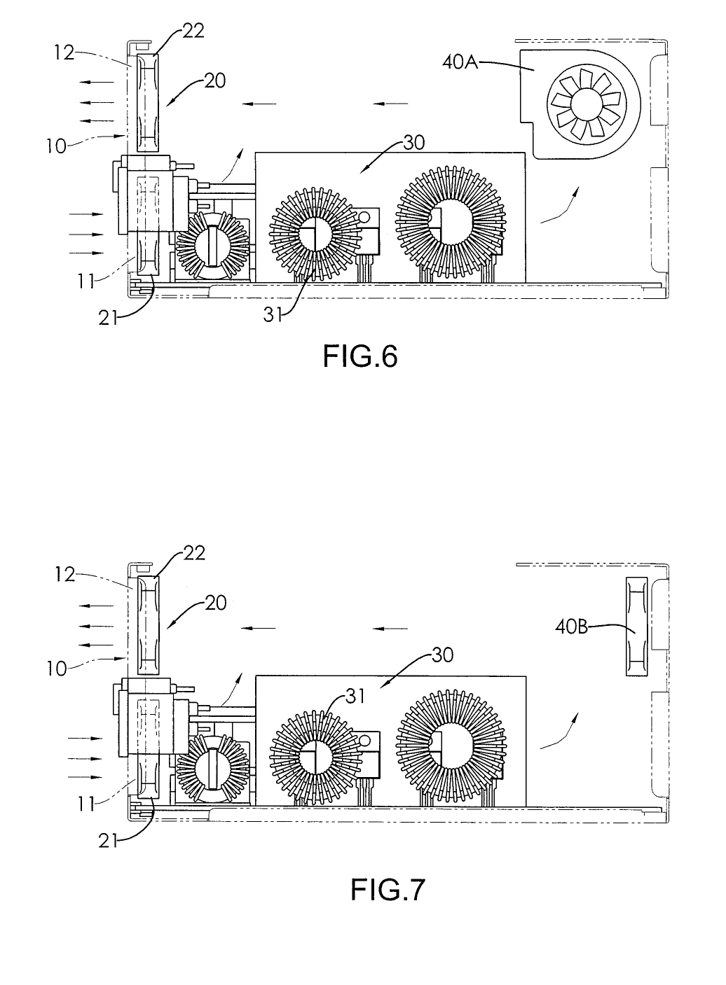

With reference to FIGS. 1, 6 and 7, a power supply in accordance with the present invention is mounted in a case (80) for a computer and comprises a shell (10), a blower assembly (20), multiple electrical components (31), an optional assistant blower (40, 40A, 40B) and an optional heat sink (50).

The case (80) comprises multiple computer components and has an inside chamber, a rear surface and a vent. The computer components are mounted in the chamber. The vent is formed through the rear surface.

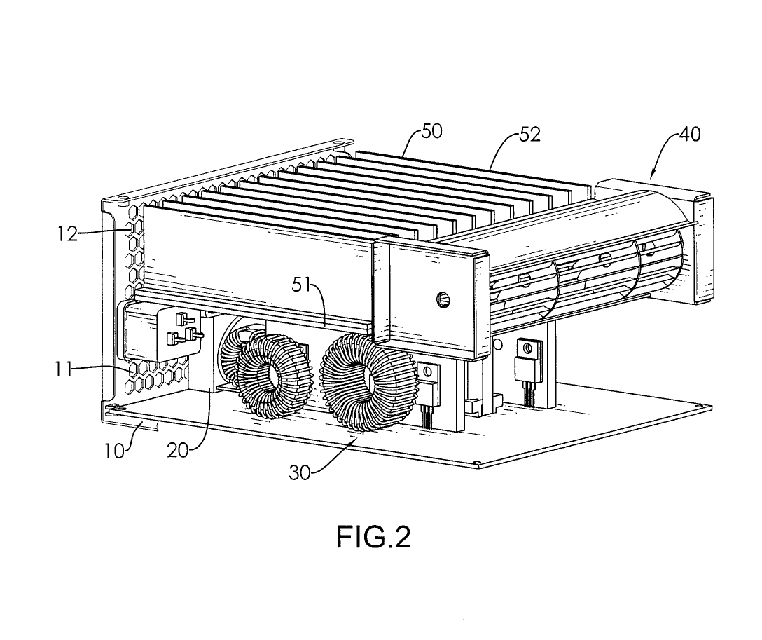

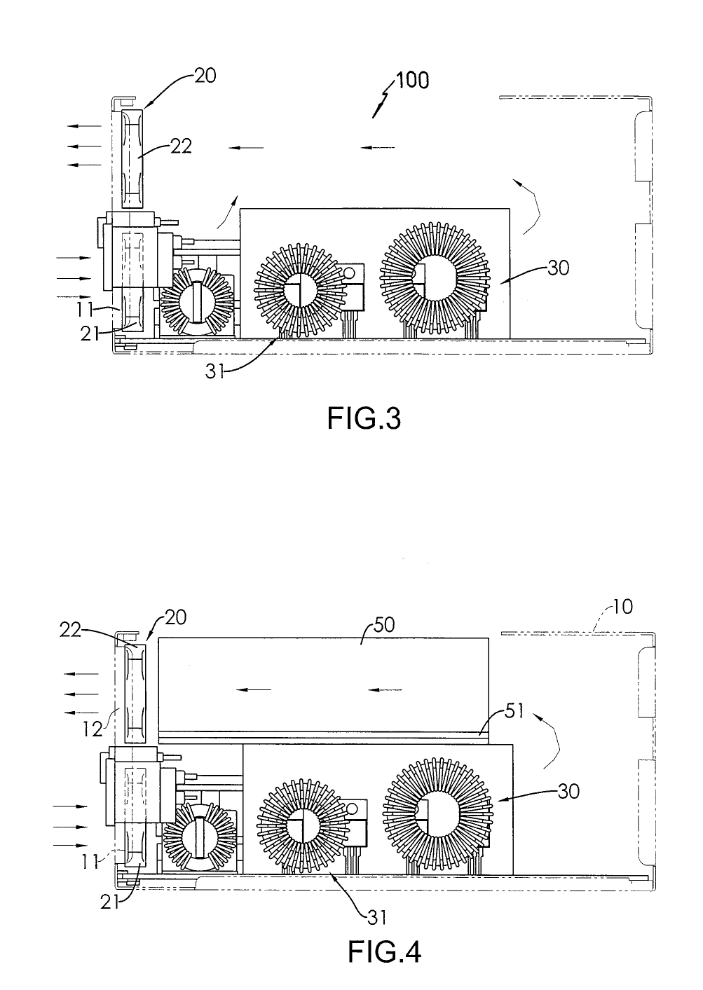

With reference to FIGS. 2 and 3, the shell (10) is mounted in the inside chamber against the rear surface of the case (80), corresponds to the vent of the case (80) and has a rear surface, a heat sink chamber (100), an electrical component chamber (30), an air inlet (11) and an air outlet (12). The rear surface of the shell (10) corresponds to the vent of the case (80). The heat sink chamber (100) is defined in the shell (10) and has a front end and a rear end. The rear end of the heat sink chamber (100) corresponds to the rear surface of the shell (10). The electrical component chamber (30) is defined in the shell (10), is parallel to the heat sink chamber (100) and has a front end and a rear end. The front end of the electrical component chamber (30) communicates with the front end of the heat sink chamber (100). The rear end of the electrical component chamber (30) corresponds to the rear surface of the shell (10). The air inlet (11) is formed through the rear surface of the shell (10), aligns with and communicates with the rear end of the electrical component chamber (30) and aligns with the vent of the case (80). The air outlet (12) is formed through the rear surface of the shell (10), aligns with and communicates with the rear end of the heat sink chamber (100) and aligns with the vent of the case (80).

With reference to FIGS. 2 and 3, the blower assembly (20) is mounted inside the shell (10) to circulate air at room temperature through the vent of the case (80), is mounted adjacent to the rear surface of the shell (10) and may have an inlet blower (21) or an outlet blower (22) or both inlet and outlet blowers (21, 22).

The inlet blower (21) is mounted near and sucks air into the air inlet (11) of the shell (10) to suck air in from the vent of the case (80).

The outlet blower (22) is mounted near and blows air out from the air outlet (12) of the shell (10) to blow air out from inside the chamber of the shell (10) out of the vent of the case (80). The electrical components (31) are mounted in the electrical component chamber (30) and generate heat when the computer operates.

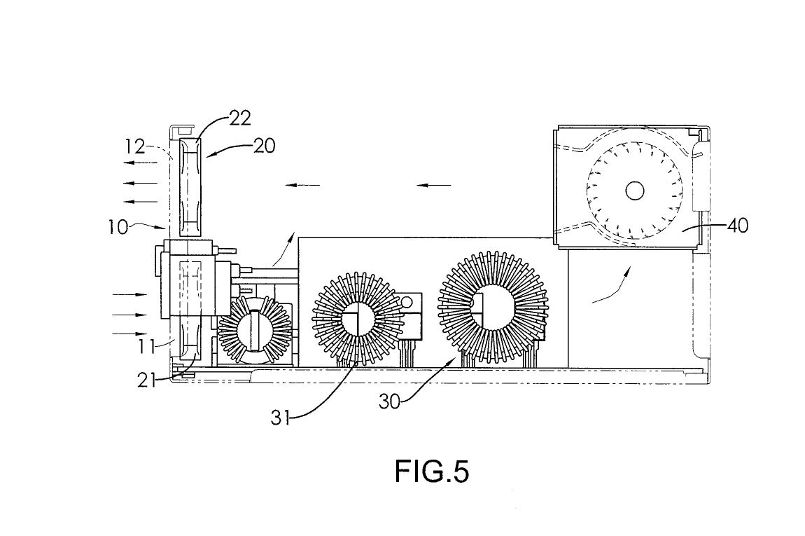

With further reference to FIGS. 5 to 7, the assistant blower (40, 40A, 40B) is mounted in the heat sink chamber (100) in the shell (10) near the front end of the heat sink chamber (100) to increase airflow over the electrical component chamber (30). The assistant blower (40) may be a cross-flow fan. The assistant blower (40A) may be a centrifugal fan. The assistant blower (40B) may be an exhaust fan.

With further reference to FIG. 4, the heat sink (50) is mounted in the heat sink chamber (100) in the shell (10) near the rear end of the heat sink chamber (100), aligns with the air outlet (12), may be mounted between the air outlet (12) of the shell (10) and the assistant blower (40, 40A, 40B), may be mounted between the outlet blower (22) and the assistant blower (40, 40A, 40B), is adjacent to the electrical component chamber (30) to conduct the heat generated by the electrical components (31) and further dissipate the heat and has a base plate (51) and multiple fins (52).

The base plate (51) is mounted between the heat sink chamber (100) and the electrical component chamber (30) to partition the heat sink chamber (100) and the electrical component chamber (30) and has a bottom surface and a top surface. The bottom surface is adjacent to the electrical component chamber (30).

The fins (52) are formed on the top surface of the base plate (51), are adjacent to the air outlet (12), may be mounted between the air outlet (12) of the shell (10) and the assistant blower (40, 40A, 40B) and may be mounted between the outlet blower (22) and the assistant blower (40, 40A, 40B).

The heat-dissipating method of the power supply of the present invention is very efficient because air at room temperature is sucked in from outside the case (80) of the computer into the shell (10). Since this air is cooler than air in the case (80) of the computer, more heat can be absorbed. The heat sink chamber (100) and the electrical component chamber (30) communicate with each other at the front end, the air sucked into the shell (10) form the rear surface has cyclic movement with cooler air interacting directly with the electrical components (31) and warming up before passing through the heat sink chamber (100) to further remove heat before being blown out of the shell (10).

Consequently, using the air at room temperature is much more efficient to cool down the power supply.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A power supply comprising
a shell having
a rear surface;
a heat sink chamber having
a front end; and
a rear end corresponding the rear surface of the shell;
an electrical component chamber being parallel to the heat sink chamber and having
a front end communicating with the front end of the heat sink chamber; and
a rear end corresponding the rear surface of the shell;
an air inlet being formed through the rear surface of the shell and aligning with and communicating with the rear end of the electrical component chamber; and
an air outlet being formed through the rear surface of the shell and aligning with and communicating with the rear end of the heat sink chamber;
a blower assembly being mounted inside the shell and being adjacent to the rear surface of the shell; and
multiple electrical components being mounted in the electrical component chamber.

2. The power supply as claimed in claim 1, wherein the blower assembly has an inlet blower mounted near and sucking air into from the air inlet of the shell.

3. The power supply as claimed in claim 1, wherein the blower assembly has an outlet blower mounted near and sucking air out from the air outlet of the shell.

4. The power supply as claimed in claim 1, wherein the blower assembly comprises
an inlet blower mounted near and sucking air into from the air inlet of the shell;
an outlet blower mounted near and sucking air out from the air outlet of the shell.

5. The power supply as claimed in claim 1 further comprising a heat sink being mounted in the heat sink chamber in the shell near the rear end of the heat sink chamber, aligning with the air outlet of the shell, being adjacent to the electrical component area and having
a base plate being mounted between the heat sink chamber and the electrical component chamber and having
a bottom surface being adjacent to the electrical component chamber; and
a top surface; and
multiple fins being formed on the top surface of the base plate and being adjacent to the air outlet of the shell.

6. The power supply as claimed in claim 2 further comprising a heat sink being mounted in the heat sink chamber in the shell near the rear end of the heat sink chamber, aligning with the air outlet of the shell, being adjacent to the electrical component area and having
a base plate being mounted between the heat sink chamber and the electrical component chamber and having
a bottom surface being adjacent to the electrical component chamber; and
a top surface; and
multiple fins being formed on the top surface of the base plate and being adjacent to the air outlet of the shell.

7. The power supply as claimed in claim 3 further comprising a heat sink being mounted in the heat sink chamber in the shell near the rear end of the heat sink chamber, aligning with the air outlet of the shell, being adjacent to the electrical component area and having
a base plate being mounted between the heat sink chamber and the electrical component chamber and having
a bottom surface being adjacent to the electrical component chamber; and
a top surface; and
multiple fins being formed on the top surface of the base plate and being adjacent to the air outlet of the shell.

8. The power supply as claimed in claim 4 further comprising a heat sink being mounted in the heat sink chamber in the shell near the rear end of the heat sink chamber, aligning with the air outlet of the shell, being adjacent to the electrical component area and having
a base plate being mounted between the heat sink chamber and the electrical component chamber and having
a bottom surface being adjacent to the electrical component chamber; and
a top surface; and
multiple fins being formed on the top surface of the base plate and being adjacent to the air outlet of the shell.

9. The power supply as claimed in claim 1 further comprising an assistant blower being mounted in the heat sink chamber in the shell near the front end of the heat sink chamber.

10. The power supply as claimed in claim 9, wherein the assistant blower is a cross-flow fan.

11. The power supply as claimed in claim 9, wherein the assistant blower is a centrifugal fan.

12. The power supply as claimed in claim 9, wherein the assistant blower is an exhaust fan.

13. The power supply as claimed in claim 8 further comprising an assistant blower being mounted in the heat sink chamber in the shell near the front end of the heat sink chamber.

14. The power supply as claimed in claim 13, wherein the assistant blower is a cross-flow fan.

15. The power supply as claimed in claim 13, wherein the assistant blower is a centrifugal fan.

16. The power supply as claimed in claim 13, wherein the assistant blower is an exhaust fan.

17. A heat-dissipating method of the power supply used in a computer having a case comprising acts of
extracting the air at room temperature from outside of the computer case into the shell of the power supply; and
leading the air to dissipate the heat generated by electrical components of the power supply.

18. The heat-dissipating method as claimed in claim 17 further comprising acts of
separating the shell into two chambers by having a base plate of a heat sink;
cycling the air extracted in the shell inside the power supply; and
blowing the air out of the shell after being warmed up by the heat generated by the electrical components.
